(19) United States
(12) Patent Application Publication
(10) Pub. No.: US 2006/0024954 A1
(43) Pub. Date: Feb. 2, 2006

(54) Copper damascene barrier and capping layer

(76) Inventors: Zhen-Cheng Wu, Hsinchu (TW); Lain-Jong Li, Hsinchu (TW); Yung-Chen Lu, Taipei (TW); Syun-Ming Jang, Hsin-chu (TW)

Correspondence Address: TUNG & ASSOCIATES;Suite 120, 838 W. Long Lake Road, Bloomfield Hills, MI, 48302, US

(21) Appl. No.: 10/910,007

(22) Filed: Aug. 2, 2004

(51) Int. Cl. H01L 21/4763

(52) U.S. Cl. 438/629; 438/636; 438/626; 438/627; 438/633

(57) ABSTRACT

A method for forming a damascene with improved electrical properties and resulting structure thereof including providing at least one dielectric insulating layer overlying a first etch stop layer; forming an anti-reflectance coating (ARC) layer prior to a photolithographic patterning process; forming at least one opening extending through a thickness portion of the at least one dielectric insulating layer and first etch stop layer according to said photolithographic patterning and an etching process; blanket depositing a barrier layer including material selected from the group consisting of silicon carbide and silicon oxycarbide to line the at least one opening; blanket depositing a refractory metal liner over the barrier layer; blanket depositing at least one metal layer to fill the at least one opening; and, removing at least the at least one metal layer overlying the at least one opening level according to a chemical mechanical polish (CMP) process.

### FIELD OF THE INVENTION

This invention generally relates to multi-layered semiconductor structures and more particularly to an improved copper damascene and method for forming the same with barrier layers and capping layers provided for improved electrical performance.

### BACKGROUND OF THE INVENTION

The escalating requirements for high density and performance associated with ultra large scale integration semiconductor wiring require increasingly sophisticated interconnection technology. As device sizes decrease it has been increasingly difficult to provide metal interconnection technology that satisfies the requirements of low RC (resistance capacitance), particularly where device sizes decrease to about 0.1 microns and smaller.

In the fabrication of semiconductor devices, increased device density and interconnect requirements has made the provision of multiple metallization levels extending through multiple dielectric insulating levels necessary. Signal transport speed is of great concern in the semiconductor processing art for obvious performance reasons. The signal transport speed of semiconductor circuitry is in part dependent on the RC (Resistance-Capacitance) time constant (delay) which varies inversely with the resistance and capacitance (RC) of the circuitry. Considerations of signal propagation speed is a driving force for adopting technology using copper interconnects extending through low dielectric constant (low-K) insulating layers to form the device circuitry.

The use of copper for device interconnects has created a number of constantly changing technological problems in semiconductor device manufacturing that must be overcome to provide reliable devices. One problem with copper interconnects has been the fact that copper readily diffuses through silicon dioxide or silicon oxide based materials, a typical IMD material. The diffusion of copper into the IMD layer reduces both the effectiveness of the electrical interconnect and the electrical insulation properties of the IMD layers. Another problem is that copper has poor adhesion to silicon oxide based IMD layers. In a parallel effort to reduce capacitance contributions to the circuitry, low dielectric constant (low-K) insulating layers, also referred to as inter-metal dielectric (IMD) or inter-level dielectric (ILD) layers, have been formed of porous silicon oxide based materials such as carbon doped oxide also frequently referred to as organo-silicate glass (OSG). The use of such low-K materials has necessitated the use of barrier layers also referred to as adhesion or barrier/adhesion layers to line damascene openings prior to filling the openings with metal, e.g., copper, to prevent copper diffusion and improve the adhesion of overlying layers. The barrier layers of the prior art have included metal nitrides such as TaN and TiN.

One problem with barrier/adhesion layers of the prior art is that their undesired contribution to the overall capacitance of the multi-level device and the added metal interconnect electrical resistance. Approaches to solve these problems have included making the barrier layer increasingly thinner as device sizes decrease below 0.25 microns to 0.1 micron and below. IN addition, efforts have been made to thin or remove remaining portions of the barrier layer overlying the low-K layer at the opening level following metal filling of the opening in a CMP process prior to subsequent processing. These approaches have introduced new problems including the undesired effect of polishing the underlying low-K IMD layer which frequently results in surface scratching and other surface defects which can degrade electrical reliability. For example, it is believed that a phenomenon referred as time dependent dielectric breakdown (TDDB) is related to IMD layer surface scratching during CMP where such scratching provides areas for charge accumulation over time which can result in spontaneous discharge and dielectric breakdown. In addition, the metal nitride barrier layers themselves are believed contribute to TDDB by providing a capacitive interface for electrical charge buildup.

Another problem with copper damascene structures formed with metal nitride barrier layers is that increasingly thin barrier layers required as device sizes are reduced to 0.1 micron and lower, causes the barrier layer to exhibit unacceptable current leakage performance. In addition, the resistance to crack propagation through IMD layers caused by thermal stresses is compromised by thinner barrier/adhesion layers.

There is therefore a need in the semiconductor processing art to provide an improved method for forming copper damascene structures including improved barrier layers and capping layers to achieve improved electrical performance of copper circuitry formed in low-K IMD layers.

It is therefore an object of the invention to provide an improved method for forming copper damascene structures including improved barrier layers and capping layers to achieve improved electrical performance of copper circuitry formed in low-K IMD layers in addition to overcoming other shortcomings and deficiencies in the prior art.

### SUMMARY OF THE INVENTION

To achieve the foregoing and other objects, and in accordance with the purposes of the present invention, as embodied and broadly described herein, the present invention provides a method for forming a damascene with improved electrical properties and resulting structure thereof.

In a first embodiment, the method includes providing at least one dielectric insulating layer overlying a first etch stop layer; forming an anti-reflectance coating (ARC) layer prior to a photolithographic patterning process; forming at least one opening extending through a thickness portion of the at least one dielectric insulating layer and first etch stop layer according to said photolithographic patterning and an etching process; blanket depositing a barrier layer including material selected from the group consisting of silicon carbide and silicon oxycarbide to line the at least one opening; blanket depositing a refractory metal liner over the barrier layer; blanket depositing at least one metal layer to fill the at least one opening; and, removing at least the at least one metal layer overlying the at least one opening level according to a chemical mechanical polish (CMP) process.

These and other embodiments, aspects and features of the invention will become better understood from a detailed description of the preferred embodiments of the invention which are described in conjunction with the accompanying drawings.

### BRIEF DESCRIPTION OF THE DRAWINGS

FIGS. 1A-1E are cross sectional views of a portion of a multiple layer semiconductor device showing the improved damascene structure at stages in fabrication according to an embodiment of the present invention.

FIGS. 2A-2E are cross sectional views of a portion of a multiple layer semiconductor device showing the improved damascene structure at stages in fabrication according to an embodiment of the present invention.

FIGS. 3A-3C are graphical data representations showing improved electrical properties of the improved damascene structure according to embodiments of the present invention.

### DETAILED DESCRIPTION OF THE PREFERRED EMBODIMENTS

Although the method of the present invention is explained by exemplary reference the formation of copper damascene structures in a multi-level semiconductor device it will be appreciated that the method of the present invention is equally applicable to the formation of dual or single damascene structures including use of other filling metals such as copper alloys, tantalum, aluminum, and alloys thereof. The method of the present invention is advantageously used to form metal damascenes, particularly copper damascenes, to improve electrical performance including reducing capacitance contributions to RC signal propagation delay, reducing current leakage, reducing the incidence of time dependent dielectric breakdown (TDDB) by improving time to dielectric breakdown, avoiding CMP of a dielectric insulating layer including a low-K dielectric insulating layer to avoid scratching defects, and increasing a resistance to stress induced crack propagation through a dielectric insulating layer.

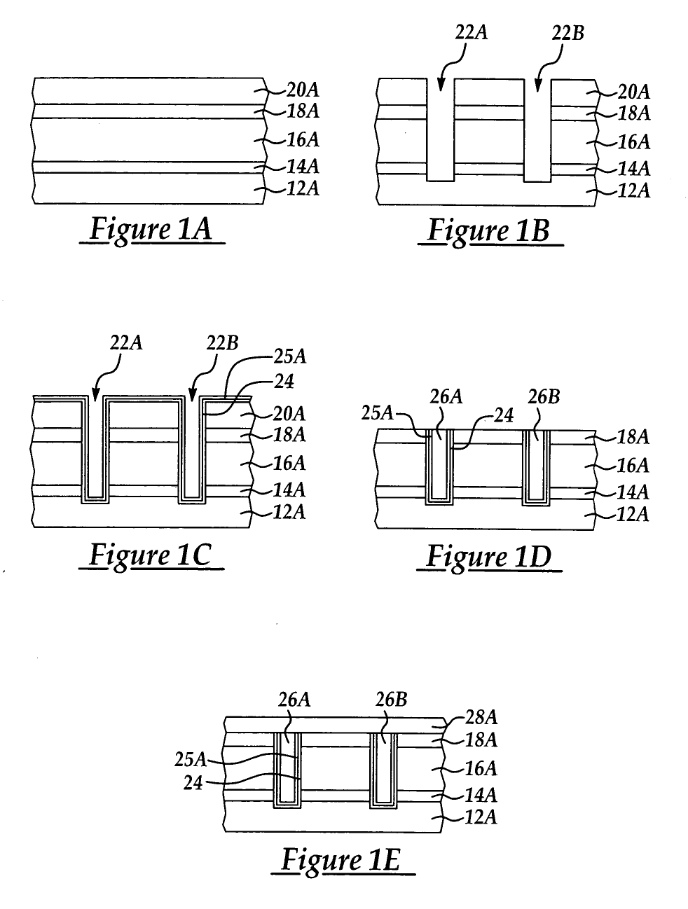

For example, referring to FIGS. 1A-1E are shown schematic representations of cross sectional portions of a multiple layer semiconductor device at stages in fabrication according to an embodiment of the present invention. For example, shown in FIG. 1A is shown a first dielectric insulating layer 12A, for example a first inter-layer dielectric (ILD) layer or inter-metal dielectric (IMD) layer formed of a conventional silicon oxide material such as undoped silicate glass (USG), fluorinated silicate glass, or doped or undoped TEOS oxide. Beginning with formation of a metallization layer e.g., M1, a conventional etch stop layer 14A, for example, silicon nitride, is formed over the ILD layer by a LPCVD, HDP-CVD, or PECVD process at a thickness of about 300 Angstroms to about 600 Angstroms.

Still referring to FIG. 1A, following the formation of the etch stop layer 14A, a low-K (low dielectric constant) inter-metal dielectric (IMD) layer 16A is formed at a thickness of about 1200 Angstroms to about 5000 Angstroms. Preferably the low-K IMD layer 16A is formed by a PECVD or HDP-CVD process to form an inorganic silicon oxide based material, for example carbon doped silicon oxide, also referred to as organo-silicate glass (OSG), formed using organo-silane precursors. For example, suitable silicon oxide based low-K materials are known by the trade names BLACK DIAMOND™, LKD™, and Orion™. Preferably the low-K IMD layer is formed having a dielectric constant of less than about 3.2.

Still referring to FIG. 1A, following formation of the low-K IMD layer 16A, according to an embodiment of the invention, silicon carbide (SiC), silicon oxynitride (SiON), silicon oxycarbide (SiOC), or silicon nitrocarbide (SiCN) capping (polishing stop) layer 18A, more preferably SiC, is formed overlying the low-K IMD layer 16A. Preferably, the SiC capping layer 18A is formed at a thickness of from about 300 Angstroms to about 500 Angstroms in a PECVD or HDP-CVD process using conventional silicon and carbon precursors.

Still referring to FIG. 1A, following formation of the silicon carbide capping layer 18A, an inorganic anti-reflectance coating (ARC) layer 20A, preferably silicon oxynitride (e.g., SiON), is deposited overlying the SiC capping layer 18A at a suitable thickness, for example from about 600 Angstroms to about 1000 Angstroms, to reduce light reflectance in a subsequent photolithographic patterning process.

Referring to FIG. 1B, a conventional photolithographic patterning and reactive ion etch (RIE) process is carried out to form openings, e.g., 22A and 22B extending through the IMD layer 16A to the first ILD layer 12A. It will be appreciated that the openings 22A and 22B may be formed to make closed communication with an underlying conductive area (not shown) to electrically communicate with a semiconductor device (not shown).

Referring to FIG. 1C, following formation of openings 22A and 22B, according to an aspect of the present invention, a barrier layer 24 of silicon oxycarbide (e.g., SiOC) or silicon carbide (e.g., Sic), more preferably SiOC, is blanket deposited by a conventional PECVD or HDP-CVD process to a thickness of about 100 Angstroms to about 300 Angstroms to line (cover the sidewalls and bottom portion) the openings 22A and 22B as well as forming a layer over the process surface. Still referring to FIG. 1C, following deposition of the SiOC barrier layer 24, an ultra-thin liner layer 25A of refractory metal such as Ta or Ti, more preferably tantalum (Ta), is blanket deposited over the SiOC layer by conventional methods to a thickness of about 40 Angstroms to about 60 Angstroms.

Referring to FIG. 1D, following deposition of the ultra-thin Ta layer 25A, a metal filling, for example copper or an alloy thereof is deposited by conventional methods including electro-chemical deposition (ECD) where a copper seed layer (not shown) is first blanket deposited over the openings 22A and 22B followed by and ECD process to blanket deposit a copper layer to fill the openings. Following copper deposition, a CMP process is carried out to removes excess copper above the opening levels including removing the ultra-thin Ta liner layer 25A, the SiOC barrier layer 24, and the ARC layer 20 above the opening level to stop on the SiC capping layer 18A thereby forming copper filled damascene structures e.g., 26A and 26B. Advantages of forming the SiC capping layer 18A include the fact that SiC is a superior polish stop to silicon nitride (e.g., SiN) or SiO₂ having a CMP removal rate of about 5 to 10 times less compared to a conventional capping layer such as SiN or SiO₂, thereby maintaining a capping layer design thickness to reduce current leakage while avoiding over-polish to induce surface polishing defect to the underlying IMD layer thereby increasing a time to dielectric breakdown. Additionally, capacitance contributions to RC signal propagation delay is reduced by both the capping layer 18A as well as the SiOC barrier layer 24 compared to metal nitride barrier layers of the prior art such as tantalum and titanium nitrides.

Referring to FIG. 1E, following the CMP process to remove materials above the SiC capping layer 18A level, a conventional etch stop layer 28A, for example silicon nitride, is deposited in a similar manner as etch stop layer 14A to begin the formation of the next metallization layer, e.g., M2.

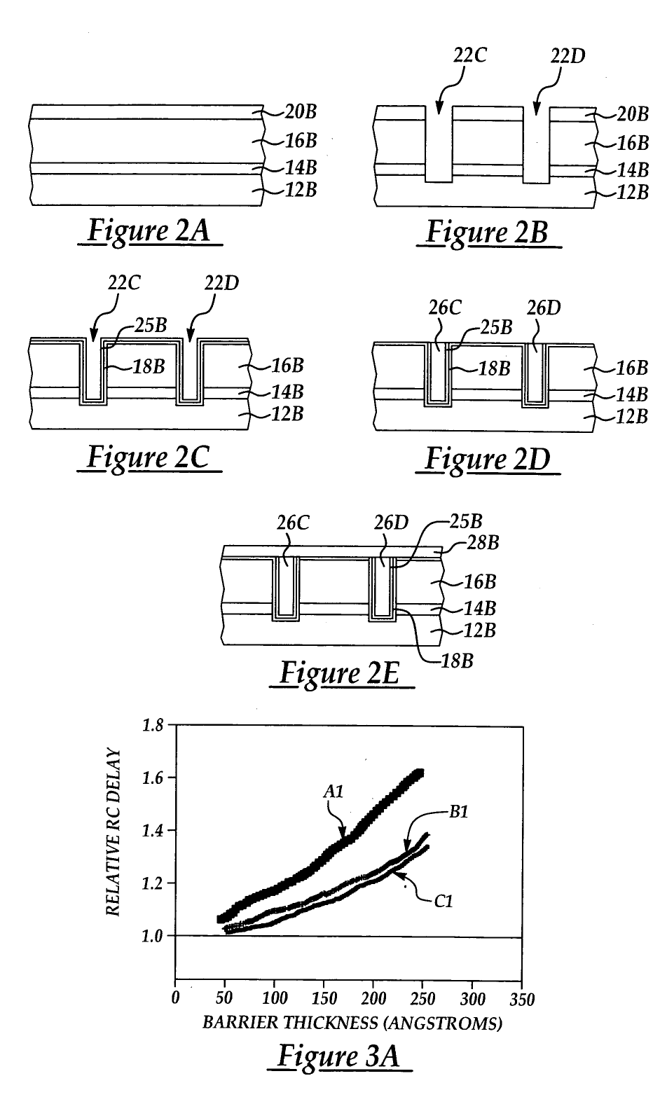

Referring to FIGS. 2A-2E, in another embodiment of the present invention, an SiC or SiOC layer is deposited to form a continuous layer, acting as both a capping and barrier layer, following formation of damascene structure openings and removal of an overlying organic ARC layer. For example referring to FIG. 2A, ILD layer 12B, etch stop layer 14B, and low-K IMD layer 16B are deposited as discussed with reference to FIG. 1A. However, in this embodiment, a conventional organic ARC layer 20B is deposited over the low-K IMD layer 16B.

Referring to FIG. 2B, damascene structure openings e.g., 22C, 22D, are formed according to a conventional photolithographic patterning and RIE etching process. Subsequently the organic ARC layer 20B is removed according to a conventional wet etching process as indicated in FIG. 2C.

Referring to FIG. 2C, following removal of the organic ARC layer 20B, according to the present embodiment, an SiC or SiOC, more preferably an SiC barrier layer 18B is blanket deposited over the low-K IMD layer 16B to line the openings e.g., 22C and 22D in addition to forming a capping (polishing stop) layer over the IMD layer 16B, preferably formed at a thickness of about 100 Angstroms to about 300 Angstroms. Next, an ultra-thin liner layer 25B of refractory metal such as Ta or Ti, more preferably tantalum (Ta), is blanket deposited over the SiC layer 18B by conventional methods to a thickness of about 40 Angstroms to about 60 Angstroms.

Referring to FIG. 2D, the processes to complete the damascene structure previously discussed are carried out a metal filling process, for example blanket deposition of a copper seed layer followed by deposition of a copper ECD filling layer. Next, a copper CMP process is carried out to stop on the barrier/polishing stop layer 18B to form copper filled damascenes e.g., 26C and 26D.

Referring to FIG. 2E, following formation of the copper damascene structures e.g., 26C and 26 to complete the metallization layer, e.g., M1 a second etch stop layer e.g. 28B, for example formed of SiN is deposited to begin the formation of the next metallization level, e.g., M2.

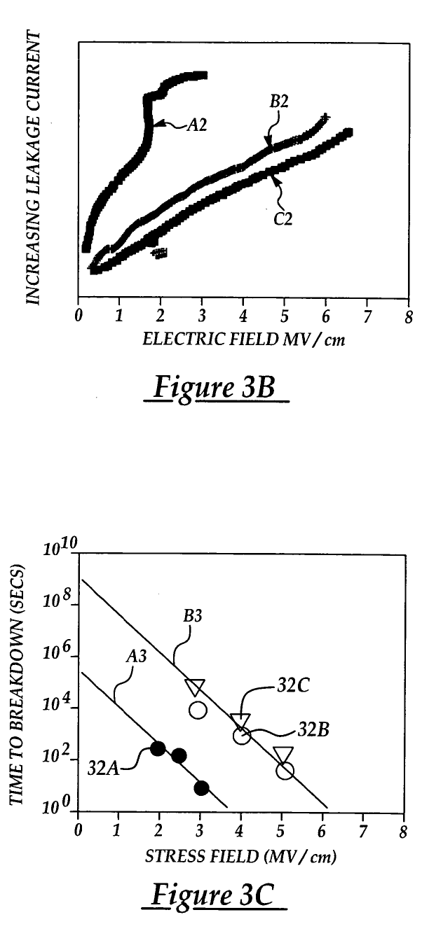

The various exemplary improvements in electrical properties of the improved copper damascene formation process including an SiC and/or SiOC capping and barrier layer are illustrated in FIGS. 3A-3C. For example, referring to FIG. 3A is shown a relative contribution to RC delayer shown on the vertical axis as a function of barrier layer or capping layer thickness in Angstroms shown on the horizontal axis for copper damascene structures. For example, the results for a conventional barrier TaN layer are represented by Line A1, while the results for SiC and SiOC are represented respectively by Lines B1 and C1. Both SiC and SiOC give superior results in terms of a lower contribution to RC delay compared to TaN having about the same dielectric constant of about 2.5.

Referring now to FIG. 3B, increasing current leakage for copper damascene structures having different barrier layers is represented on the vertical axis as a function of applied electric field in MV/cm, represented on the horizontal axis. The results for SiC (Line B2) and SiOC (Line C2) barrier layers indicate superior current leakage properties compared to TaN (Line A2) barrier layers.

Referring now to FIG. 3C, is shown time to dielectric breakdown on the vertical as a function of applied stress field in units of MV/cm on the horizontal axis. Line A3, represents a linear response derived for TaN data measurements, e.g. data points 32A, while line B3, represents a linear response derived from SiC data measurements, e.g., 32B and SiOC data measurements, e.g., 32C. The relative measurements represent the performance of copper damascene structures with barrier layers as well as capping layers formed according to embodiments of the present invention compared to TaN barrier layers according to the prior art.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method for forming a damascene with improved electrical properties comprising the steps of:
providing at least one dielectric insulating layer overlying a first etch stop layer;
forming at least one opening extending through a thickness portion of the at least one dielectric insulating layer and first etch stop layer;
depositing a barrier layer comprising a material selected from the group consisting of silicon carbide and silicon oxycarbide to line the at least one opening;
depositing a refractory metal liner over the barrier layer;
depositing at least one metal layer to fill the at least one opening; and,
removing at least the at least one metal layer overlying the at least one opening level according to a chemical mechanical polish (CMP) process.

2. The method of claim 1, wherein a silicon carbide polishing stop layer is formed overlying and contacting the at least one dielectric insulating layer prior to forming an ARC layer overlying and contacting said polishing stop layer.

3. The method of claim 2, wherein the ARC layer is an inorganic ARC layer comprising silicon oxynitride left in place following the step of forming at least one opening.

4. The method of claim 2, wherein the barrier layer comprises silicon oxycarbide.

5. The method of claim 2, wherein said CMP process stops on said silicon carbide polishing stop layer.

6. The method of claim 1, wherein the ARC layer is an organic ARC layer which is removed following the step of forming the at least one opening.

7. The method of claim 6, wherein the barrier layer comprises silicon carbide formed to overlie and contact said at least one dielectric insulating layer wherein said CMP process stops on said silicon carbide barrier layer.

8. The method of claim 1, wherein the metal is selected from the group consisting of copper, aluminum, tantalum, and alloys thereof.

9. The method of claim 1, wherein the refractory metal liner is formed at a thickness of from about 40 Angstroms to about 60 Angstroms.

10. The method of claim 9, wherein the refractory metal liner is selected from the group consisting of tantalum and titanium.

11. The method of claim 9, wherein the refractory metal liner consists primarily of tantalum.

12. The method of claim 1, wherein the at least one dielectric insulating layer comprises a dielectric insulating layer selected from the group consisting of carbon doped oxide formed from organo-silane precursors.

13. A method for forming a damascene with improved electrical properties comprising the steps of:
providing an IMD layer comprising carbon doped oxide overlying a first etching stop layer;
forming a capping layer comprising a material selected from the group consisting of silicon carbide and silicon oxycarbide overlying and contacting said IMD layer;
forming an anti-reflectance coating (ARC) layer comprising silicon oxynitride overlying and contacting the capping layer;
forming at least one opening extending through a thickness of said IMD layer and said first etch stop layer;
depositing a barrier layer comprising a material selected from the group consisting of silicon carbide and silicon oxycarbide lining said at least one opening;
depositing a liner of tantalum over the silicon oxycarbide barrier layer;
depositing a copper layer filling said at least one opening; and,
removing layers overlying the capping layer by a chemical mechanical polish (CMP) process.

14. The method of claim 13, wherein the IMD layer comprises a dielectric constant of less than about 3.2.

15. The method of claim 13, wherein the line width of the at least one opening is less than or equal to about 0.25 microns.

16. The method of claim 13, wherein the capping layer is formed at a thickness of from about 300 Angstroms to about 500 Angstroms.

17. The method of claim 13, wherein the barrier layer is formed at a thickness of from about 100 Angstroms to about 300 Angstroms.

18. A method for forming a damascene with improved electrical properties comprising the steps of:
providing an IMD layer comprising carbon doped oxide overlying a first etching stop layer;
forming an organic anti-reflectance coating (ARC) layer overlying and contacting the IMD layer;
forming at least one opening extending through a thickness of said IMD layer and first etch stop layer;
removing the organic ARC layer;
blanket depositing a barrier layer comprising a material elected from the group consisting of silicon carbide and silicon oxycarbide to line the at least one opening and to overlie and contact the IMD layer;
depositing a liner of tantalum over the silicon carbide barrier layer;
depositing a copper layer to fill the at least one opening; and,
removing layers overlying the barrier layer according to a chemical mechanical polish (CMP) process.

19. The method of claim 18, wherein the IMD layer comprises a dielectric constant of less than about 3.2.

20. The method of claim 18, wherein the line width of the at least one opening is less than or equal to about 0.25 microns.

21. The method of claim 18, wherein the barrier layer is formed at a thickness of from about 100 Angstroms to about 300 Angstroms.

22. A damascene structure with an improved barrier layer and polishing stop comprising:
at least one metal filled opening extending through a thickness portion of at least one dielectric insulating layer;
said at least one metal filled opening lined with a barrier layer comprising a material selected from the group consisting of silicon carbide and silicon oxycarbide;
wherein, the at least one metal filled opening comprises an upper opening level adjacent to a polishing stop layer comprising a material selected from the group consisting of silicon carbide and silicon oxycarbide overlying and contacting the at least one dielectric insulating layer.

23. The damascene structure of claim 22, wherein the metal is selected from the group consisting of copper, aluminum, tantalum, and alloys thereof.

24. The damascene structure of claim 22, wherein the barrier layer further comprises an uppermost layer of refractory metal selected from the group consisting of tantalum and titanium.

25. The damascene structure of claim 24, wherein the uppermost layer of refractory metal is from about 40 Angstroms to about 60 Angstroms thick.

26. The damascene structure of claim 22, wherein the barrier layer is from about 100 Angstroms to about 300 Angstroms thick.

27. The damascene structure of claim 22, wherein the polishing stop layer is from about 300 Angstroms to about 500 Angstroms thick.

28. The damascene structure of claim 22, wherein the polishing stop layer and the barrier layer comprise a continuous layer having a thickness of from about 100 Angstroms to about 300 Angstroms thick.

29. The damascene structure of claim 22, wherein the at least one dielectric insulating layer comprises a dielectric constant of less than about 3.2.

30. The damascene structure of claim 22, wherein the line width of the at least one metal filled opening is less than or equal to about 0.25 microns.

31. The damascene structure of claim 22, wherein the polishing stop layer comprises silicon carbide and the barrier layer comprises silicon oxycarbide.

32. The damascene structure of claim 22, wherein the polishing stop layer and the barrier layer comprise a continuous layer of silicon carbide.
